(19) United States
(12) Patent Application Publication
(10) Pub. No.: US 2026/0334304 A1
(43) Pub. Date: Oct. 22, 2026

(54) SEMICONDUCTOR PACKAGE AND MANUFACTURING METHOD THEREOF

(71) Applicant: Orient Semiconductor Electronics, Limited, Kaohsiung City (TW)

(72) Inventors: YUEH-MING TUNG, Kaohsiung City (TW); CHIA-MING YANG, Kaohsiung City (TW); PO-YEN YEN, Kaohsiung City (TW); HUNG-YU cHENG, Kaohsiung City (TW); PIN-CHUN WANG, Kaohsiung City (TW)

(21) Appl. No.: 19/182,681

(22) Filed: Apr. 18, 2025

(30) Foreign Application Priority Data
Jan. 8, 2025 (TW) 114100733

(51) Int. Cl. H01L 25/16; H01L 21/56; H01L 23/00; H01L 23/498; H01L 23/538; H01L 25/00; H01L 25/065; H10B 80/00; H10D 80/30

(52) U.S. Cl. CPC H10W 90/00; H10B 80/00; H10D 80/30; H10W 70/60; H10W 70/611; H10W 74/016; H10W 90/701; H10W 72/823; H10W 90/24; H10W 90/724; H10W 90/754

(57) ABSTRACT

The present disclosure provides a semiconductor package. The semiconductor package includes a substrate, a memory die, a controller die, a molding compound, a plurality of conductive columns, a redistribution layer and a processor die. The substrate has opposing first surface and second surface. The memory die is disposed on the first surface of the substrate to be electrically connected to the substrate. The controller die is disposed on the first surface of the substrate. The molding compound is formed on the first surface of the substrate to cover the controller die and the memory die. The conductive columns are disposed on the first surface of the substrate to be electrically connected to the substrate. The redistribution layer is formed on the molding compound to be electrically connected to the controller die and the conductive columns. The processor die is disposed on the second surface of the substrate to be electrically connected to the substrate. The present disclosure further provides a method of manufacturing the above semiconductor package.

### CROSS-REFERENCE TO RELATED APPLICATIONS

The present application is based on and claims priority to Taiwanese Application Number 114100733, filed Jan. 8, 2025, the disclosure of which is hereby incorporated by reference herein in its entirety.

### FIELD OF THE DISCLOSURE

This disclosure relates to a semiconductor package and a manufacturing method thereof, and more particularly relates to a flash memory package, and a manufacturing method thereof.

### BACKGROUND OF THE DISCLOSURE

At present, the memory and controller die in a flash memory card are packaged into a single package and then mounted into a system-on-chip package.

However, such design utilizes a surface-mount technology (SMT) that is not only difficult to work with, but also requires the use of three-dimensional steel plates.

### SUMMARY

In view of the above, the present disclosure provides a semiconductor package and a manufacturing method thereof to solve the above problems.

In one embodiment, the semiconductor package of the present disclosure includes a substrate, a memory die, a controller die, a molding compound, a plurality of conductive columns, a redistribution layer and a processor die. The substrate has opposing first surface and second surface. The memory die is disposed on the first surface of the substrate to be electrically connected to the substrate. The controller die is disposed on the first surface of the substrate. The molding compound is formed on the first surface of the substrate to cover the controller die and the memory die. The conductive columns are disposed on the first surface of the substrate to be electrically connected to the substrate. The redistribution layer is formed on the molding compound to be electrically connected to the controller die and the conductive columns. The processor die is disposed on the second surface of the substrate to be electrically connected to the substrate.

In one embodiment, the method of manufacturing a semiconductor package comprises: providing a substrate having opposing first surface and second surface; disposing a memory die on the first surface of the substrate, the memory die being electrically connected to the substrate; disposing a plurality of first conductive bumps on a controller die; disposing the controller die on the first surface of the substrate; disposing a plurality of conductive columns on the first surface of the substrate, the conductive columns being electrically connected to the substrate; forming a molding compound on the first surface of the substrate to cover the controller die, the memory die and the first conductive bumps; grinding the molding compound to expose the first conductive bumps and the conductive columns; forming a redistribution layer on the molding compound, the redistribution layer being electrically connected to the first conductive bumps and the conductive columns; and disposing a processor die on the second surface of the substrate, the processor die being electrically connected to the substrate.

The semiconductor packages of the present disclosure may be manufactured in lower costs and higher production yields.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package of the present disclosure.

FIGS. 2 to 10 illustrate the method of manufacturing the semiconductor package of FIG. 1.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

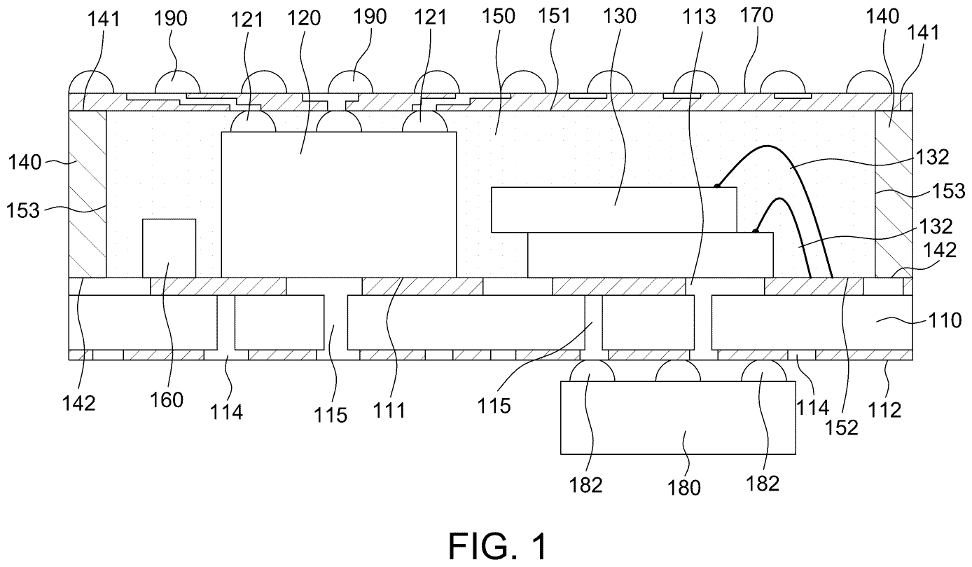

Referring to FIG. 1, the semiconductor package of the present disclosure includes a substrate 110 having opposing first surface 111 and second surface 112, and the first surface 111 and the second surface 112 are located on different planes. The first surface 111 and the second surface 112 of the substrate 110 are formed with a conductive trace 113 and a conductive trace 114 thereon, respectively. The conductive traces 113 and 114 are electrically connected to each other by a plurality of conductive vias 115 penetrating the substrate 110 from the first surface 111 to the second surface 112.

In one embodiment, the substrate 110 may be a single-layer or multi-layer circuit board, a redistribution layer (RDL) substrate or a glass substrate.

One or more, for example, a plurality of memory dies 130 is disposed on the first surface 111 of the substrate 110. The memory dies 130 each have an active surface and a back surface opposite to the active surface. The memory dies 130 may be stacked vertically or stepwise on the substrate 110 and adhered to the substrate 110 with adhesive or epoxy resin. When the memory dies 130 are stacked on the substrate 110 in a stepwise manner, they may be electrically connected to the conductive trace 113 on the first surface 111 of the substrate 110 by means of a plurality of bonding wires 132, i.e. the respective ends of the bonding wires 132 are connected to the active surfaces of the memory dies 130 and the first surface 111 of the substrate 110.

A controller die 120 is disposed on the first surface 111 of the substrate 110. The controller die 120 has an active surface and a back surface opposite to the active surface. The back surface of the controller die 120 is adhered to the first surface 111 of the substrate 110 with adhesive or epoxy resin. The controller die 120 is disposed side by side with the memory dies 130.

A plurality of first conductive bumps 121 is disposed on the active surface of the controller die 120. The first conductive bumps 121 are electrically connected to the controller die 120. The first conductive bumps 121 may be metal bumps formed on the active surface of the controller die 120 using a bumping process. The first conductive bumps 121 may be composed of eutectic, lead free, high lead materials, or copper pillars.

A plurality of passive components 160 may be mounted on the first surface 111 of the substrate 110 as desired.

A molding compound 150 is formed on the first surface 111 of the substrate 110 to cover the controller die 120, the memory dies 130, the passive components 160 and the bonding wires 132. The molding compound 150 does not completely cover the first conductive bumps 121, and each of the first conductive bumps 121 is partially exposed from the molding compound 150.

The molding compound 150 has a first surface 151, a second surface 152, and a plurality of third surfaces 153. The first surface 151 and the second surface 152 are located on different planes. The third surfaces 153 connect the first surface 151 and the second surface 152. The second surface 152 of the molding compound 150 is in contact with the first surface 111 of the substrate 110.

A plurality of conductive columns 140 is disposed on the first surface 111 of the substrate 110 to surround the molding compound 150. The conductive columns 140 are in contact with the third surfaces 153 of the molding compound 150. The conductive columns 140 each have opposing first surface 141 and second surface 142, and the first surface 141 and the second surface 142 are located on different planes. The conductive columns 140 are vertically fixed on the substrate 110 and electrically connected to the conductive trace 113 on the first surface 111 of the substrate 110. The second surfaces 142 of the conductive columns 140 are in contact with the first surface 111 of the substrate 110. The first surfaces 141 of the conductive columns 140 are not covered by the molding compound 150.

A redistribution layer 170 is formed on the first surface 151 of the molding compound 150. There are conductive traces formed in the redistribution layer 170. The redistribution layer 170 is in contact with and electrically connected to the first conductive bumps 121 and the first surfaces 141 of the conductive columns 140. The controller die 120 is electrically connected to the redistribution layer 170 through the first conductive bumps 121.

A processor die 180 is disposed on the second surface 112 of the substrate 110. The processor die 180 has an active surface and a back surface opposite to the active surface. A plurality of second conductive bumps 182 is disposed on the active surface of the processor die 180. The second conductive bumps 182 are electrically connected to the processor die 180 and sandwiched between the processor die 180 and the substrate 110. The processor die 180 is electrically connected to the conductive columns 140 through the second conductive bumps 182 and the conductive traces 113, 114 on the substrate 110.

A plurality of solder balls 190 is disposed on and electrically connected to the redistribution layer 170. The memory dies 130 may be electrically connected to the solder balls 190 through the bonding wires 132, the substrate 110, the conductive columns 140 and the redistribution layer 170. The processor die 180 may be electrically connected to the solder balls 190 through the second conductive bumps 182, the substrate 110, the conductive columns 140 and the redistribution layer 170. The controller die 120 may be electrically connected to the solder balls 190 through the first conductive bumps 121 and the redistribution layer 170. In this way the memory dies 130, the controller die 120 and the processor die 180 may be electrically connected to an external circuit through the solder balls 190.

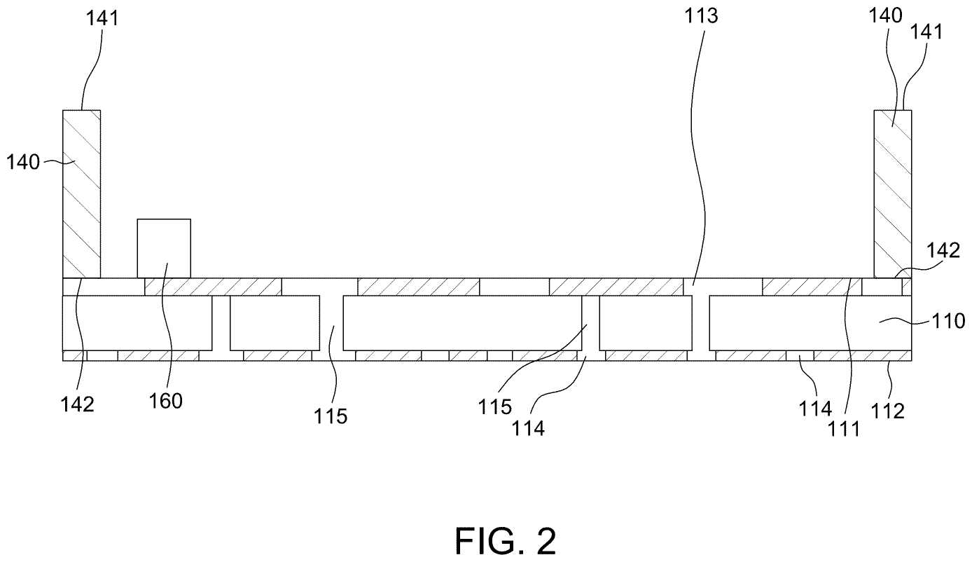

Referring to FIGS. 2 to 10, which illustrate a method of manufacturing the semiconductor package of FIG. 1. As shown in FIG. 2, a substrate 110 is provided. The substrate 110 has opposing first surface 111 and second surface 112, and the first surface 111 and the second surface 112 are located on different planes. The first surface 111 and the second surface 112 of the substrate 110 are formed with a conductive trace 113 and a conductive trace 114 thereon, respectively. The conductive traces 113 and 114 are electrically connected to each other by a plurality of conductive vias 115 penetrating the substrate 110 from the first surface 111 to the second surface 112.

In one embodiment, the substrate 110 may be a single-layer or multi-layer circuit board, a redistribution layer substrate or a glass substrate.

A plurality of conductive columns 140 is disposed on the first surface 111 of the substrate 110. The conductive columns 140 each have opposing first surface 141 and second surface 142, and the first surface 141 and the second surface 142 are located on different planes. The conductive columns 140 are vertically fixed on the substrate 110 and electrically connected to the conductive trace 113 on the first surface 111 of the substrate 110. The second surfaces 142 of the conductive columns 140 are in contact with the first surface 111 of the substrate 110.

A plurality of passive components 160 may be mounted on the first surface 111 of the substrate 110 as desired.

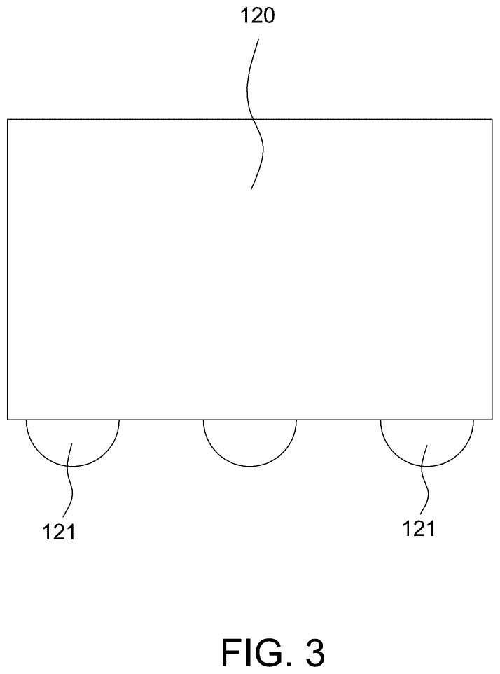

As shown in FIG. 3, a controller die 120 is provided. The controller die 120 has an active surface and a back surface opposite to the active surface. A plurality of first conductive bumps 121 is disposed on the active surface of the controller die 120. The first conductive bumps 121 are electrically connected to the controller die 120. The first conductive bumps 121 may be metal bumps formed on the active surface of the controller die 120 using a bumping process. The first conductive bumps 121 may be composed of eutectic, lead free, high lead materials, or copper pillars.

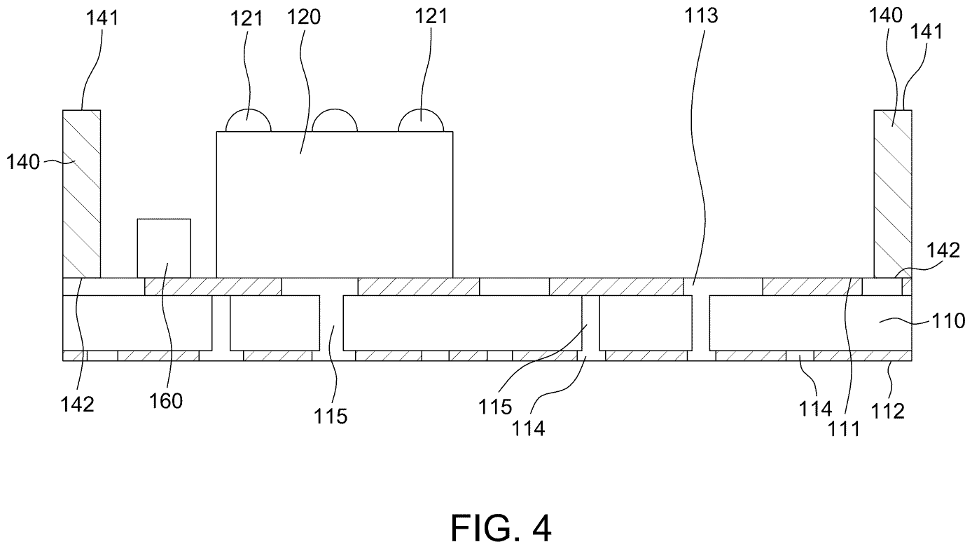

As shown in FIG. 4, the back surface of the controller die 120 is then adhered to the first surface 111 of the substrate 110 with adhesive or epoxy resin.

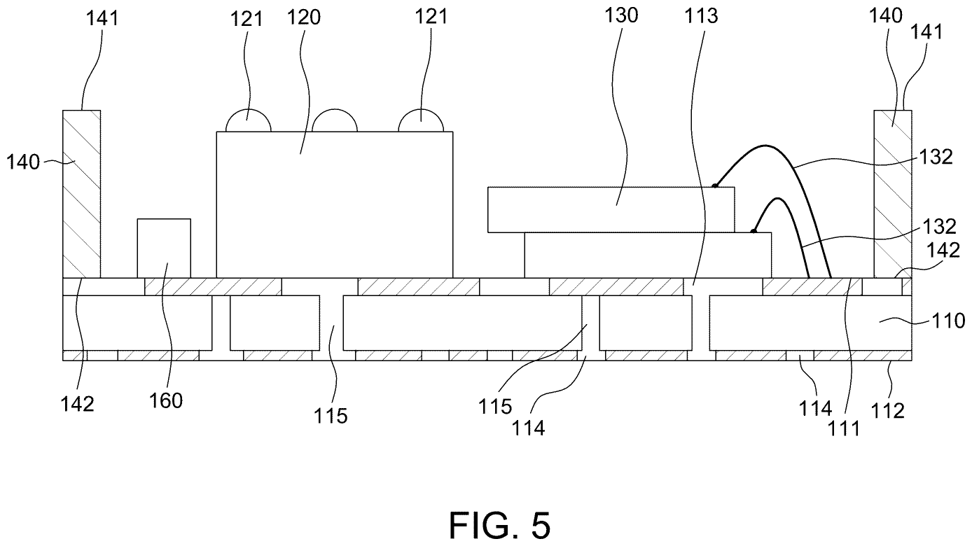

As shown in FIG. 5, one or more, for example, a plurality of memory dies 130 is then disposed on the first surface 111 of the substrate 110. The memory dies 130 are adhered to the substrate 110 with adhesive or epoxy resin. The memory dies 130 each have an active surface and a back surface opposite to the active surface. The memory dies 130 are electrically connected to the conductive trace 113 on the first surface 111 of the substrate 110 by means of a plurality of bonding wires 132.

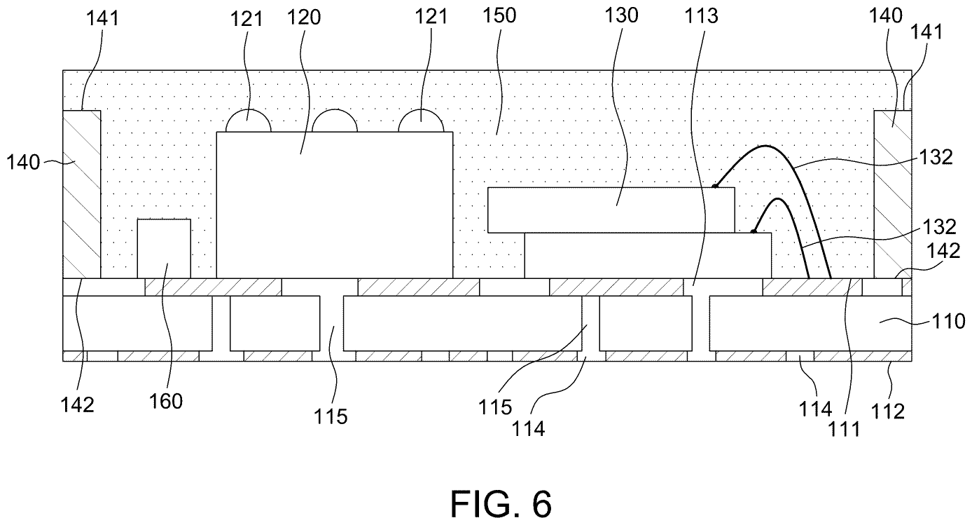

As shown in FIG. 6, a molding compound 150 is then formed on the first surface 111 of the substrate 110 to cover the controller die 120, the memory dies 130, the passive components 160, the first conductive bumps 121 and the bonding wires 132.

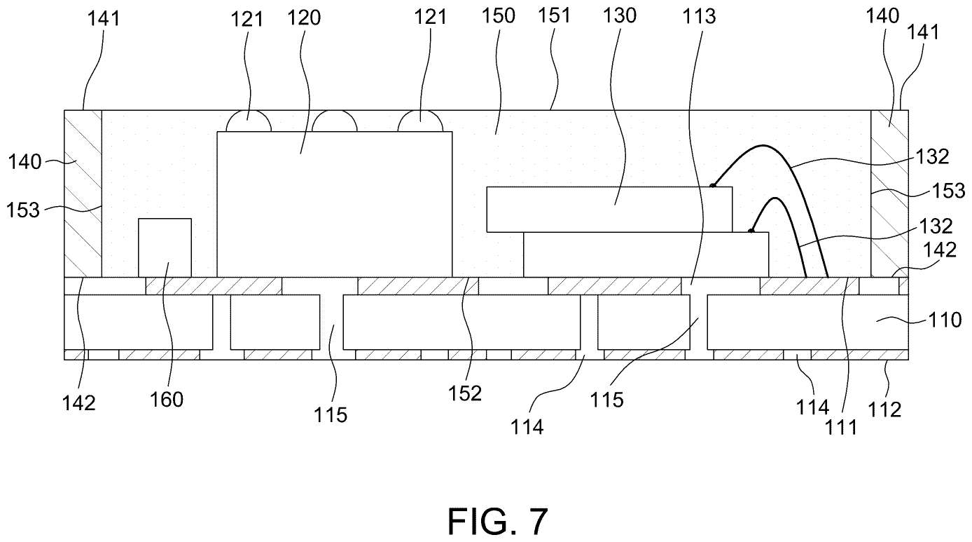

As shown in FIG. 7, the molding compound 150 is then ground to reduce its thickness so that tops of the first conductive bumps 121 and the first surfaces 141 of the conductive columns 140 are exposed.

The molding compound 150, when partially removed, has a first surface 151, a second surface 152 and a plurality of third surfaces 153. The first surface 151 and the second surface 152 are located on different planes. The third surfaces 153 connect the first surface 151 and the second surface 152.

The second surface 152 of the molding compound 150 is in contact with the first surface 111 of the substrate 110. The conductive columns 140 are around the molding compound 150 and in contact with the third surfaces 153 of the molding compound 150.

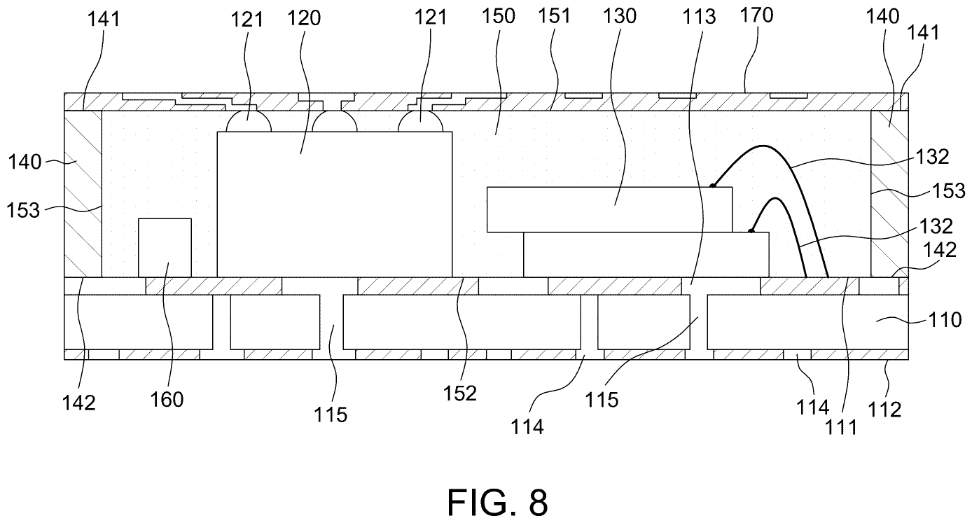

As shown in FIG. 8, a redistribution layer 170 is then formed on the first surface 151 of the molding compound 150. There are conductive traces formed in the redistribution layer 170. The redistribution layer 170 is in contact with and electrically connected to the first conductive bumps 121 and the first surfaces 141 of the conductive columns 140. The controller die 120 is electrically connected to the redistribution layer 170 through the first conductive bumps 121.

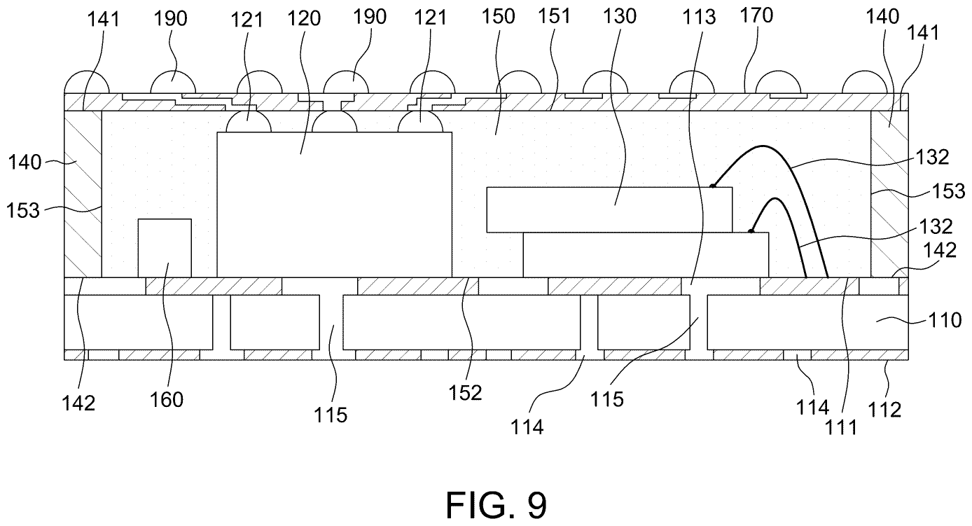

As shown in FIG. 9, a plurality of solder balls 190 is then formed on and electrically connected to the redistribution layer 170.

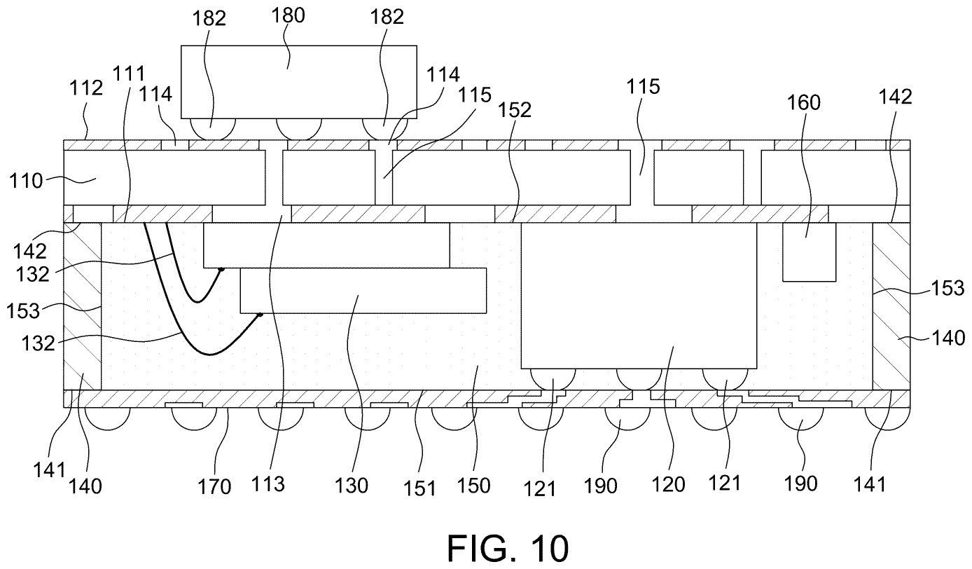

As shown in FIG. 10, a processor die 180 is provided. The processor die 180 has an active surface and a back surface opposite to the active surface. A plurality of second conductive bumps 182 is formed on the active surface of the processor die 180. The second conductive bumps 182 are electrically connected to the processor die 180.

Afterwards, the package shown in FIG. 9 is inverted. The processor die 180 is attached to the second surface 112 of the substrate 110 using flip chip technology such that the second conductive bumps 182 are sandwiched between the processor die 180 and the substrate 110. The processor die 180 is electrically connected to the conductive columns 140 through the second conductive bumps 182 and the conductive traces 113, 114 on the substrate 110.

In the semiconductor package of the present disclosure, the memory dies 130 may be electrically connected to the solder balls 190 through the bonding wires 132, the substrate 110, the conductive columns 140 and the redistribution layer 170. The processor die 180 may be electrically connected to the solder balls 190 through the second conductive bumps 182, the substrate 110, the conductive columns 140 and the redistribution layer 170. The controller die 120 may be electrically connected to the solder balls 190 through the first conductive bumps 121 and the redistribution layer 170. In this way the memory dies 130, the controller die 120 and the processor die 180 may be electrically connected to an external circuit through the solder balls 190.

The semiconductor packages of the present disclosure may be manufactured in lower costs and higher production yields.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A semiconductor package, comprising:
a substrate having opposing first surface and second surface;
a memory die disposed on the first surface of the substrate to be electrically connected to the substrate;
a controller die disposed on the first surface of the substrate;
a molding compound formed on the first surface of the substrate to cover the controller die and the memory die;
a plurality of conductive columns disposed on the first surface of the substrate to be electrically connected to the substrate;
a redistribution layer formed on the molding compound to be electrically connected to the controller die and the conductive columns; and
a processor die disposed on the second surface of the substrate to be electrically connected to the substrate.

2. The semiconductor package as claimed in claim 1, further comprising:
a plurality of first conductive bumps disposed between the controller die and the redistribution layer, the first conductive bumps being electrically connected to the controller die and the redistribution layer.

3. The semiconductor package as claimed in claim 1, further comprising:
a plurality of second conductive bumps disposed between the processor die and the substrate, the second conductive bumps being electrically connected to the processor die and the substrate.

4. The semiconductor package as claimed in claim 1, wherein the conductive columns are around the molding compound.

5. The semiconductor package as claimed in claim 1, further comprising:
a plurality of bonding wires disposed on the substrate to be electrically connected to the memory die and the substrate.

6. The semiconductor package as claimed in claim 1, further comprising:
a plurality of solder balls formed on and electrically connected to the redistribution layer.

7. A method of manufacturing a semiconductor package, comprising:
providing a substrate having opposing first surface and second surface;
disposing a memory die on the first surface of the substrate, the memory die being electrically connected to the substrate;
disposing a plurality of first conductive bumps on a controller die;
disposing the controller die on the first surface of the substrate;
disposing a plurality of conductive columns on the first surface of the substrate, the conductive columns being electrically connected to the substrate;
forming a molding compound on the first surface of the substrate to cover the controller die, the memory die and the first conductive bumps;
grinding the molding compound to expose the first conductive bumps and the conductive columns;
forming a redistribution layer on the molding compound, the redistribution layer being electrically connected to the first conductive bumps and the conductive columns; and
disposing a processor die on the second surface of the substrate, the processor die being electrically connected to the substrate.

8. The method as claimed in claim 7, further comprising:
disposing a plurality of second conductive bumps between the processor die and the substrate.

9. The method as claimed in claim 7, further comprising:
disposing a plurality of bonding wires on the substrate, the bonding wires being electrically connected to the memory die and the substrate.

10. The method as claimed in claim 7, further comprising:
forming a plurality of solder balls on the redistribution layer.
